(19) United States
(12) Patent Application Publication
(10) Pub. No.: US 2008/0048742 A1
(43) Pub. Date: Feb. 28, 2008

(54) PHASE COMPARISON SIGNAL PROCESSING CIRCUIT

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 11/778,696

(22) Filed: Jul. 17, 2007

(30) Foreign Application Priority Data
Jul. 24, 2006 (JP) 2006-200742

(51) Int. Cl. H03L 7/06; H03K 3/86

(52) U.S. Cl. 327/158; 327/236

(57) ABSTRACT

The present invention provides a phase comparison signal processing circuit which processes an output rectangular wave signal of a digital phase comparator of a PLL, expands a pullable-in frequency width of the PLL and shortens a synchronization time. The phase comparison signal processing circuit includes a first signal path which is parallel-connected between a voltage shifter for converting a rectangular wave signal to a bipolar signal and an output terminal and comprises a rectifying circuit, an integration holding circuit, a differentiation circuit, a gate circuit, a voltage hold circuit and a common addition circuit, a second signal path comprising a rectifying circuit, an integration holding circuit, a differentiation circuit, a gate circuit, a voltage hold circuit and the addition circuit, and a control signal generator for individually controlling the integration holding circuits and the gate circuits of the first and second signal paths. The rectification of the bipolar signal, integration and holding of rectified voltages, differentiation of integrated hold values, holding of differentiated outputs and addition of hold voltages are carried out at the first and second signal paths thereby to output a processed signal.

### RELATED/PRIORITY APPLICATION

This application claims priority with respect to Japanese Application No. 2006-200742 filed Jul. 24, 2006.

### BACKGROUND OF THE INVENTION

1. Field of the Invention

The present invention relates to a phase comparison signal processing circuit, and particularly to a phase comparison signal processing circuit which is connected between a phase comparator and a loop filter employed in a phase-locked loop (PLL) and processes a rectangular wave signal for frequency comparison outputted from the phase comparator and supplied to the loop filter and which enlarges a pull-in frequency width at the PLL and improves a synchronous characteristic such as shortening of a synchronization time.

2. Description of the Related Art

A PLL has been used in a large number of electronic equipment each requiring an oscillator in recent years because the oscillation frequency of a voltage controlled oscillator can automatically be controlled to a predetermined frequency by using a relatively simple constituting means. When the PLL is used in a first local oscillation circuit in a multi-channel access (MCA) receiver and a first local oscillation circuit in a frequency scanning receiver, it is often used in a state of being incorporated in a frequency synthesizer. When the PLL is used in the first local oscillation circuit of the multi-channel access receiver or the frequency scanning receiver, it is desirable to set a phase lock-in time of the PLL as short as possible. When the PLL is used in a first local oscillation circuit of such a receiver as to search or scan known receive signals in general, it is desired that a pull-in frequency width is as broad as possible.

The simplest method for solving such a contradictory technical means in the PLL is to set a reference frequency signal of a reference signal generator to a high frequency when an oscillation frequency signal outputted from a voltage controlled oscillator and the reference frequency signal outputted from the reference signal generator are phase-compared by a phase comparator. If the reference frequency used in the PLL is set high in this case, then the corner frequency of a loop filter, i.e., the frequency at which the attenuation characteristic of the loop filter changes stepwise can be enhanced. As a result, the time response of the loop filter can be shortened.

However, the setting of the reference frequency signal of the reference signal generator in the PLL to the high frequency is actually subject to constraints due to the reasons to be described later where the PLL is used in the first local oscillation circuit in the multi-channel access receiver and the first local oscillation circuit in the frequency scanning receiver, for example. The reasons are as follows. At the multi-channel access receiver and the frequency scanning receiver, a radio wave determined according to a frequency assignment is actually assigned so as to assume a specific frequency interval, for example, either a frequency at a 25 kHz interval or a frequency at a 12.5 kHz interval, and the reference frequency used in the PLL needs to be selected equal to this frequency interval. Thus, it is not possible to freely set the reference frequency as mentioned above.

Therefore, the multi-channel access receiver or the frequency scanning receiver normally holds the reference frequency of the reference signal generator at the PLL as it is and sets the corner frequency of the loop filter as high as possible, thereby solving such trouble. When, however, the corner frequency is set high, a ripple component contained in an output signal of the loop filter increases correspondingly, and a spurious component increases within the oscillation signal (carrier signal) outputted from the voltage controlled oscillator. Accordingly, an improvement in the response speed at the PLL and a reduction in the spurious component of the oscillation signal (carrier signal) are in a reciprocal relationship.

On the other hand, it is general that as the phase comparator used in the PLL in the multi-channel access receiver or the frequency scanning receiver, a digital circuit implemented in IC form, i.e., a digital phase comparator such as an exclusive-OR gate circuit, an RS flip-flop circuit, a phase frequency comparator (PFC) or the like is used rather than an analog circuit such as a ring modulator, an analog multiplier or the like as in the prior art. When the digital phase comparator is used in the PLL, a rectangular wave signal outputted from the digital phase comparator is subjected to deformation processing before application of the comparison output of the digital phase comparator to the loop filter without applying the same to the loop filter as it is as in the prior art, thereby reducing the ripple component contained in the rectangular wave signal and attaining an increase in the frequency of the ripple component. In doing so, the corner frequency of the loop filter can be enhanced and the loop gain of the PLL can be increased.

That is, when the digital phase comparator of the PLL is constituted of an exclusive OR circuit, the rectangular wave signal outputted from the digital phase comparator is of a signal having a pulse width proportional to an instantaneous difference in phase between a reference signal and a signal to be compared. A duty factor thereof changes at a speed of a difference frequency x time. Thus, it is considered that since the duty factor is simply represented in the form of a pulse sequence proportional to the difference in phase between the reference signal and the compared signal, the rectangular wave signal is easy to use seemingly. As to frequency spectrums held in the rectangular wave signal, however, complex spectrums containing a frequency component corresponding to the sum of spectrums of the reference signal and the compared signal and a frequency component corresponding to the difference between the spectrums thereof occur due to the product of spectrums defined as rectangular waves, contained in the reference signal and the compared signal. In this case, the voltage controlled oscillator used in the PLL is used to extract a dc component proportional to the difference in phase between the reference signal and the compared signal from the rectangular wave signal and perform frequency control using the extracted dc component. Therefore, there was a need to sufficiently attenuate the frequency component of the reference signal at the loop filter.

### SUMMARY OF THE INVENTION

The present invention has been made on the basis of such a technological background. An object of the present invention is to provide a phase comparison signal processing circuit capable of, when a rectangular wave signal outputted from a digital phase comparator is supplied to a loop filter, processing the rectangular wave signal thereby to expand a pullable-in frequency width at a PLL and shorten a synchronization time.

In order to attain the above object, there is provided a phase comparison signal processing circuit according to the present invention, including first constituting means which is connected between a phase comparator and a loop filter in a PLL constituted of a voltage controlled oscillator, the phase comparator, the loop filter and a reference signal generator and processes a rectangular wave signal outputted from the phase comparator, and which comprises a voltage shifter that converts the rectangular wave signal into a bipolar signal; first and second signal paths both parallel-connected between the voltage shifter and an output terminal for outputting a processed signal and each comprising a rectifying circuit, an integration holding circuit, a differentiation circuit, a gate circuit, a voltage hold circuit, and an addition circuit common to both signal paths; and a control signal generator which is driven by the rectangular wave signal and generates control signals for individually controlling the respective integration holding circuits and the respective gate circuits of the first and second signal paths, wherein in the first signal path, the rectifying circuit extracts a positive portion of the bipolar signal, the integration holding circuit integrates the extracted positive signal and holds an integrated value thereof during a period up to extraction of the positive signal and the following positive signal, the differentiation circuit detects a hold voltage at the time that the hold voltage of the integration holding circuit is changed to a reference voltage, as a differential output, and the gate circuit and the voltage hold circuit output the differential output of the differentiation circuit as an interval-period hold voltage, and wherein in the second signal path, the same processing as that executed in the first signal path is effected on a negative portion of the bipolar signal, whereby a processed signal produced by adding the respective hold voltages obtained in the first and second signal paths is outputted from the output terminal.

The phase comparison signal processing circuit includes second constituting means wherein in the first constituting means, a gate circuit and a voltage hold circuit which form a delay-processed signal obtained by delaying the processed signal outputted from the common addition circuit by a half cycle, using a control signal generated from the control signal generator, and an averaging circuit which is supplied with the processed signal outputted from the common addition circuit and the delay-processed signal and averages signal levels thereof, are cascade-connected between an output end of the addition circuit common to the first and second signal paths and the output terminal, and an averaging-processed signal in which incoming time intervals of portions to be added become ½ and a difference in amplitude therebetween becomes ½, is outputted from the output terminal connected to the averaging circuit.

The phase comparison signal processing circuit according to the first constituting means is configured based on the following principle of operation.

That is, a rectangular wave signal outputted from a digital phase comparator is normally a binary signal constituted of a low level L (“0”) and a high level H (“1”). It is made up of a positive pulse sequence in which a positive pulse (high level H) intermittently arrives with respect to a reference level (low level). In the present invention, however, in order to integrate the reference level (low level L) portion of the rectangular wave signal and its positive pulse (high level H) respectively, the reference level of the rectangular wave signal is changed and the rectangular wave signal is converted to bipolar signals constituted of a positive pulse and a negative pulse with respect to the reference level. The so-obtained bipolar signals are respectively supplied to the first and second signal paths each having the rectifying circuit, the integration holding circuit, the differentiation circuit, the gate circuit, the voltage hold circuit and the common addition circuit.

In the first signal path, the rectifying circuit selectively extracts each positive portion in the bipolar signal. The integration holding circuit integrates and holds the selectively extracted positive portion. The differentiation circuit differentiates a variation portion at the time that the integration-hold value is reduced to the reference level, thereby to form a negative impulse equal to the integration-hold value. The gate circuit and the voltage hold circuit hold a negative voltage value equal to the integration-hold value obtained by differentiation and supply the negative voltage value to the addition circuit. Likewise, in the second signal path, the rectifying circuit selectively extracts each negative portion in the bipolar signal. The integration holding circuit integrates and holds the selectively extracted negative portion. The differentiation circuit differentiates a variation portion at the time that the integration-hold value rises to the reference level, thereby to form a positive impulse equal to the integration-hold value. The gate circuit and the voltage hold circuit hold a positive voltage value equal to the integration-hold value obtained by differentiation and supply the positive voltage value to the addition circuit. At this time, the addition circuit adds the supplied negative and positive voltage values together and thereby outputs a processed signal corresponding to a voltage value equal to the difference between the negative voltage value and the positive voltage value.

When the processed signal is supplied to the loop filter in the PLL, the frequency of the voltage controlled oscillator of the PLL is adjusted based on a dc component outputted from the loop filter. When the frequency of the voltage controlled oscillator is adjusted, the times at which the reference level (low level) of the rectangular wave signal outputted from the phase comparator of the PLL and the positive pulse (high level H) thereof arrive become equal to each other, so that the processed signal outputted from the phase comparison signal processing circuit is brought to the voltage value equal to the reference level.

As described above in detail, the phase comparison signal processing circuit brings about advantageous effects in that since the rectangular wave signal outputted from the phase comparator in the PLL is subjected to deformation processing to make it possible to increase the dc component in the rectangular wave signal and suppress the magnitude of a high frequency component contained in the dc component, the corner frequency of the loop filter can be transitioned in a high frequency direction as compared with the corner frequency of the conventional loop filter, so that the response speed of the PLL can be increased and the frequency width indicative of a synchronizable range of the PLL can be expanded.

In this case, to which extent the response speed of the PLL can be accelerated at the phase comparison signal processing circuit and to which extent the frequency width indicative of the synchronizable range can be expanded thereat differ depending upon various setting conditions such as the used format of digital phase comparator, the initial difference in phase between the oscillation signal of the voltage controlled oscillator and the reference signal, the loop gain of the PLL and the like. It is difficult to cite specific numeric values by way of example distinctly. However, both the response speed and the synchronizable range are generally improved a few times than before the use of the phase comparison signal processing circuit.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 is a block circuit diagram showing a fragmentary configuration of a PLL that uses a phase comparison signal processing circuit according to the present invention;

FIG. 2 relates to a first embodiment of a PLL phase comparison signal processing circuit according to the present invention and is a block circuit diagram showing its fragmentary configuration;

FIG. 3 is a waveform diagram illustrating signals obtained at respective parts in the PLL phase comparison signal processing circuit illustrated in FIG. 2;

FIG. 4 relates to a second embodiment of a PLL phase comparison signal processing circuit according to the present invention; and

FIG. 5 is a waveform diagram showing signals obtained at respective parts in the PLL phase comparison signal processing circuit illustrated in FIG. 4.

### DETAILED DESCRIPTION OF THE PREFERRED EMBODIMENTS

Preferred embodiments of the present invention will be explained hereinafter with reference to the accompanying drawings.

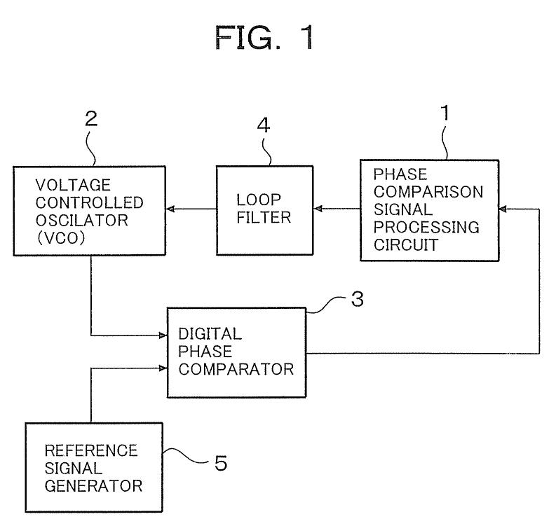

FIG. 1 is a block circuit diagram showing a fragmentary configuration of a PLL that uses a phase comparison signal processing circuit according to the present invention.

As shown in FIG. 1, the PLL comprises a phase comparison signal processing circuit 1 according to the present invention, a voltage controlled oscillator (VCO) 2, a digital phase comparator 3, a loop filter 4 and a reference signal generator 5. The phase comparison signal processing circuit 1 has an input end connected to an output end of the digital phase comparator 3, and an output end connected to an input end of the loop filter 4. The voltage controlled oscillator 2 has an input end connected to an output end of the loop filter 4, an output end connected to a first mixer of an unillustrated receiver and a first input end of the digital phase comparator 3. The digital phase comparator 3 has a second input end connected to an output end of the reference signal generator 5.

The PLL illustrated in FIG. 1 is identical in configuration to the well-known PLL except for the component parts of the phase comparison signal processing circuit 1 according to the present invention. The operation of other component parts other than the operation of the component parts of the phase comparison signal processing circuit 1 is almost the same as the operation of this type of known PLL. Further, since the operation of such a PLL is well known, the description of the operation of this PLL will be omitted.

### First Preferred Embodiment

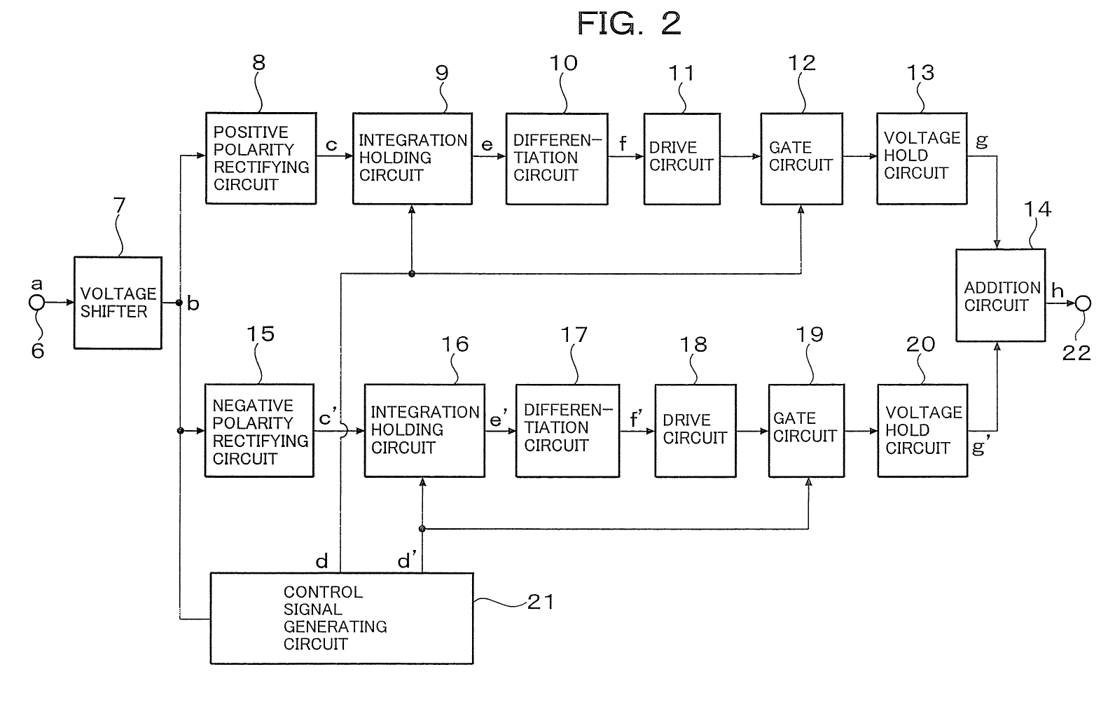

Next, FIG. 2 shows a first embodiment of a phase comparison signal processing circuit according to the present invention and is a block circuit diagram illustrating its fragmentary configuration.

As shown in FIG. 2, the phase comparison signal processing circuit according to the first embodiment comprises an input terminal 6, a voltage shifter 7, a positive polarity rectifying circuit 8, an integration holding circuit 9, a differentiation circuit 10, a drive circuit 11, a gate circuit 12, a voltage hold circuit 13, an addition circuit 14, a negative polarity rectifying circuit 15, an integration holding circuit 16, a differentiation circuit 17, a drive circuit 18, a gate circuit 19, a voltage hold circuit 20, a control signal generator or generating circuit 21, and an output terminal 22. In this case, the positive polarity rectifying circuit 8, the integration holding circuit 9, the differentiation circuit 10, the drive circuit 11, the gate circuit 12, the voltage hold circuit 13 and the addition circuit 14 form a first signal path. The negative polarity rectifying circuit 15, the integration holding circuit 16, the differentiation circuit 17, the drive circuit 18, the gate circuit 19, the voltage hold circuit 20 and the addition circuit 14 form a second signal path.

The voltage shifter 7 has an input end connected to the input terminal 6 and an output end connected to an input end of the positive polarity rectifying circuit 8, an input end of the negative polarity rectifying circuit 15 and an input end of the control signal generating circuit 21 respectively. The positive polarity rectifying circuit 8 has an output end connected to an input end of the integration holding circuit 9. The integration holding circuit 9 has an output end connected to an input end of the differentiation circuit 10 and a control end connected to a first control end of the control signal generating circuit 21. The differentiation circuit 10 has output end connected to an input end of the drive circuit 11, and the drive circuit 11 has an output end connected to an input end of the gate circuit 12. The gate circuit 12 has an output end connected to an input end of the voltage hold circuit 13 and a control end connected to the first control end of the control signal generating circuit 21. The voltage hold circuit 13 has an output end connected to a first input end of the addition circuit 14. The negative polarity rectifying circuit 15 has an output end connected to an input end of the integration holding circuit 16. The integration holding circuit 16 has an output end connected to an input end of the differentiation circuit 17 and a control end connected to a second control end of the control signal generating circuit 21. The differentiation circuit 17 has an output end connected to an input end of the drive circuit 18, and the drive circuit 18 has an output end connected to an input end of the gate circuit 19. The gate circuit 19 has an output end connected to an input end of the voltage hold circuit 20 and a control end connected to the second control end of the control signal generating circuit 21. The voltage hold circuit 13 has an output end connected to a second input end of the addition circuit 14. The addition circuit 14 has an output end connected to an output terminal 22.

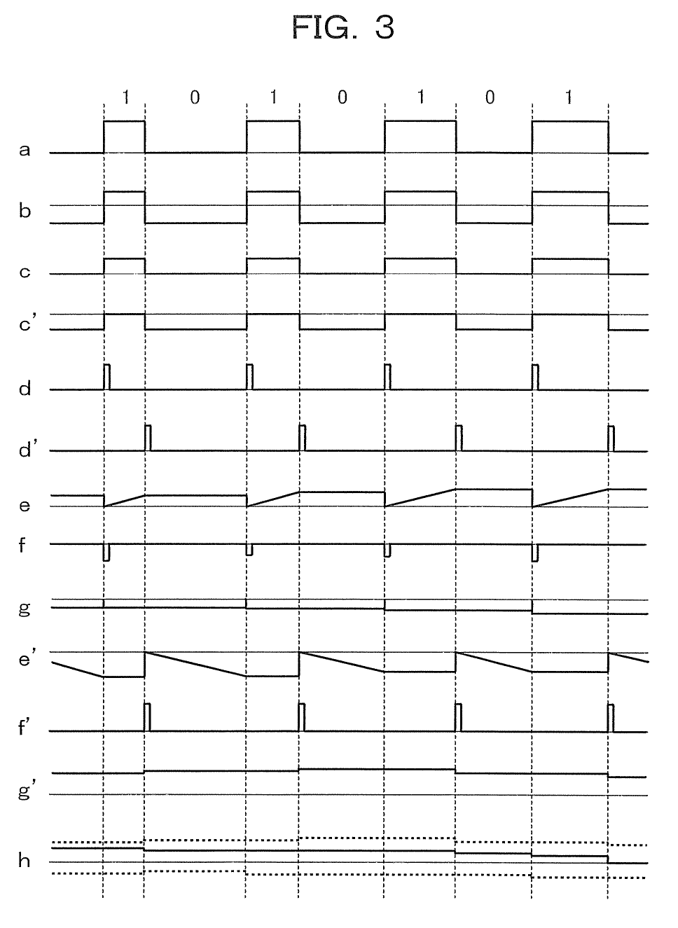

FIG. 3 is a waveform diagram showing signal waveforms produced at respective parts employed in the phase comparison signal processing circuit according to the first embodiment.

In the signal waveform diagram shown in FIG. 3, a indicates a rectangular wave signal (unipolar signal) waveform supplied to the input terminal 6. b indicates a rectangular wave signal (bipolar signal) waveform changed in reference level by the voltage shifter 7, c indicates the waveform of each positive portion of a bipolar signal rectified and extracted by the positive polarity rectifying circuit 8, c′ indicates the waveform of each negative portion of a bipolar signal rectified and extracted by the negative polarity rectifying circuit 15, d indicates a control pulse waveform outputted from the first control end of the control signal generating circuit 21, d′ indicates a control pulse waveform outputted from the second control end of the control signal generating circuit 21, e indicates an integration-hold voltage value at the integration hold circuit 9, f indicates a negative polarity pulse waveform outputted from the differentiation circuit 10, and g indicates a negative polarity hold voltage value outputted from the voltage hold circuit 13. e′ indicates an integration-hold voltage value at the integration holding circuit 16, f′ indicates a positive polarity pulse waveform outputted from the differentiation circuit 17, g′ indicates a positive polarity hold voltage value outputted from the voltage hold circuit 20, and h indicates an additional hold voltage value obtained by adding two hold voltages outputted from the addition circuit 14.

The operation of the phase comparison signal processing circuit according to the first embodiment will now be explained in conjunction with the waveform diagram shown in FIG. 3.

When a rectangular wave signal (refer to the waveform a shown in FIG. 3) outputted from the digital phase comparator 3 is supplied to the voltage shifter 7 via the input terminal 6, the voltage shifter 7 raises the reference level of the rectangular wave signal to the middle level of each positive polarity pulse to change the same to a bipolar signal (refer to the waveform b shown in FIG. 3). The voltage shifter 7 supplies the bipolar signal to the positive polarity rectifying circuit 8, the negative polarity rectifying circuit 15 and the control signal generating circuit 21. The positive polarity rectifying circuit 8 rectifies each positive portion of the bipolar signal and selects and extracts the same (refer to the waveform c shown in FIG. 3), followed by being supplied to the following integration holding circuit 9. The integration holding circuit 9 integrates the corresponding positive portion during an incoming period of each positive portion and holds its integrated value (refer to the waveform e shown in FIG. 3) until the integrated value is reduced to the reference level according to the supply of the control pulse (refer to the waveform d shown in FIG. 3) from the control signal generating circuit 21 since the incoming period of the next positive portion was reached. When the integration-hold value of the integration holding circuit 9 is reduced to the reference level, the differentiation circuit 10 generates a negative pulse of a level equal to the integration-hold value (refer to the waveform f shown in FIG. 3), and the drive circuit 11 supplies the negative pulse to the gate circuit 12. The gate circuit 12 and the voltage hold circuit 13 hold the voltage value of the supplied negative pulse during a period from the time when the control pulse (refer to the waveform d shown in FIG. 3) is supplied from the control signal generating circuit 21 to the time when the following control pulse is supplied therefrom. Then, the voltage hold circuit 13 outputs its negative hold voltage value (refer to the waveform g shown in FIG. 3).

On the other hand, the negative polarity rectifying circuit 15 rectifies each negative portion of the bipolar signal and selects and extracts the same (refer to the waveform c′ shown in FIG. 3), followed by its supply to the following integration holding circuit 16. The integration holding circuit 16 integrates the corresponding negative portion during an incoming period of each negative portion and holds its integrated value until the integrated value rises to the reference level according to the supply of the control pulse (refer to the waveform d′ shown in FIG. 3) from the control signal generating circuit 12 since the incoming period of the next negative portion was reached (refer to the waveform e′ shown in FIG. 3). When the integration-hold value of the integration holding circuit 16 is reduced to the reference level, the differentiation circuit 17 generates a positive pulse of a level equal to the integration-hold value (refer to the waveform f′ shown in FIG. 3), and the drive circuit 18 supplies the positive pulse to the gate circuit 19. The gate circuit 19 and the voltage hold circuit 20 hold the voltage value of the supplied positive pulse during a period from the time when the control pulse is supplied from the control signal generating circuit 21 (refer to the waveform d′ shown in FIG. 3) to the time when the following control pulse is supplied therefrom. Then, the voltage hold circuit 20 outputs its positive hold voltage value (refer to the waveform g′ shown in FIG. 3). Thereafter, the addition circuit 14 adds the negative hold voltage value (refer to the waveform g shown in FIG. 3) and the positive hold voltage value (refer to the waveform g′ shown in FIG. 3) and outputs a hold voltage value corresponding to the difference therebetween. And a processed signal (refer to the waveform h shown in FIG. 3) in which each addition part arrives periodically is obtained at the output terminal 22 and supplied to the following-stage loop filter.

Thus, according to the phase comparison signal processing circuit according to the first embodiment, the rectangular wave signal outputted from the digital phase comparator is converted to the processed signal changed in amplitude in a stepped wave fashion in the PLL, after which it is added to the loop filter, instead of the direct addition of the rectangular wave signal outputted from the digital phase comparator to the loop filter. Therefore, each ripple component contained in the signal added to the loop filter can greatly be reduced, so the corner frequency of the loop filter can be enhanced. Correspondingly, the response speed of a loop can be accelerated and besides the loop gain of the PLL can be increased.

### Second Preferred Embodiment

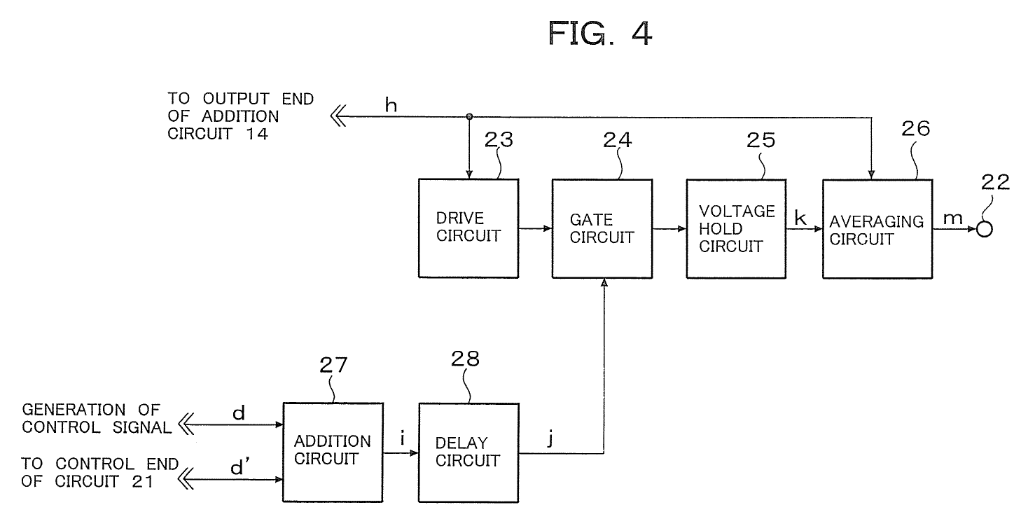

Next, FIG. 4 shows a second embodiment of a phase comparison signal processing circuit according to the present invention and is a block circuit diagram showing its fragmentary configuration. FIG. 4 illustrates an example in which all frequency spectrums contained in a processed signal changed in amplitude in a stepped wave fashion are diffused into the side of a frequency twice higher than the first embodiment.

As shown in FIG. 4, the phase comparison signal processing circuit according to the second embodiment is one wherein as compared with the phase comparison signal processing circuit according to the first embodiment, a drive circuit 23, a gate circuit 24, a voltage hold circuit 25 and an averaging circuit 26 are cascade-connected between an output terminal of an addition circuit 14 and an output terminal 2, and an addition circuit 27 for adding control pulses of a control signal generating circuit 21 and a delay circuit 28 for delaying the added control pulse of the addition circuit 27 by a half cycle are provided in addition to the above. As constituent elements other than the above, the same constituent elements as those in the phase comparison signal processing circuit 1 according to the first embodiment are used. The drive circuit 23 has an input end connected to an output end of the addition circuit 14 and an output end connected to an input end of the gate circuit 24. The gate circuit 24 has an output end connected to an input end of the voltage hold circuit 25 and a control end connected to an output end of the delay circuit 28. The averaging circuit 26 has a first input end connected to an output end of the addition circuit 14, a second input end connected to an output end of the voltage hold circuit 25, and an output end connected to the output terminal 22.

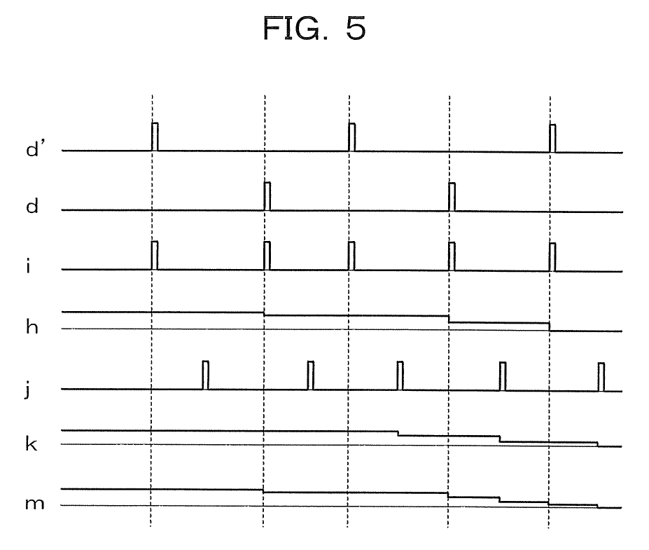

FIG. 5 is a waveform diagram showing signal waveforms produced in respective parts of the phase comparison signal processing circuit according to the second embodiment. The same signal waveforms as those developed at the respective parts illustrated in FIG. 3 are given the symbols attached to the signal waveforms illustrated in FIG. 3.

In the signal waveform diagram illustrated in FIG. 5, i indicates an addition control pulse waveform obtained by adding two control pulses (refer to waveforms d and d′ in FIG. 5) outputted from the control signal generating circuit 21 together by the addition circuit 27, j indicates a control pulse waveform obtained by delaying the added control pulse by a half cycle by means of the delay circuit 28, k indicates a delay-processed signal waveform obtained by delaying a processed signal (refer to a waveform h shown in FIG. 5) outputted from the voltage hold circuit 25 by a half cycle, and m indicates an averaging-processed signal waveform obtained by averaging the processed signal (refer to the waveform h shown in FIG. 5) and the delay-processed signal waveform (refer to the waveform k shown in FIG. 5) by the averaging circuit 26.

The operation of the phase comparison signal processing circuit according to the second embodiment will now be explained using the waveform diagram shown in FIG. 5.

The operation of the phase comparison signal processing circuit according to the second embodiment is identical to the respective operations at the first and second signal paths. The operation of the control signal generating circuit 21 related to the first and second signal paths is identical to its corresponding operation of the phase comparison signal processing circuit according to the first embodiment. Thus, the processed signal (refer to the waveform h shown in FIG. 5) is led out to the output end of the addition circuit 14. Since these component parts are identical in operation to the phase comparison signal processing circuit according to the first embodiment and their operational explanations are dual, they will be omitted. The operation of ones other than these component parts will be explained.

The drive circuit 23 supplies a processed signal (refer to the waveform h shown in FIG. 5) outputted from the addition circuit 14 to the following gate circuit 24. At this time, the addition circuit 27 adds two control pulses (refer to the waveforms d and d′ shown in FIG. 5) outputted from the control signal generating circuit 21 to form an added control pulse (refer to the waveform i shown in FIG. 5). The delay circuit 28 delays the so-formed added control pulse by a half cycle to form a delayed control pulse (refer to the waveform j shown in FIG. 5), which in turn is supplied to the gate circuit 24. Thus, the gate circuit 24 extracts a voltage at the supply of the delayed control pulse at the supplied processed signal (refer to the waveform h shown in FIG. 5) and supplies the voltage to the voltage hold circuit 25. The voltage hold circuit 25 holds the supplied voltage to the same voltage value until the following voltage is supplied, and obtains a delay-processed signal (refer to the waveform k shown in FIG. 5) produced by delaying the processed signal (refer to the waveform h shown in FIG. 5) by a half cycle at the output of the voltage hold circuit 25. Thereafter, the averaging circuit 26 determines the average or mean of the supplied processed signal (refer to the waveform h shown in FIG. 5) and delayed-processed signal (refer to the waveform k shown in FIG. 5) and interpolates those processed signals, whereby the averaging-processed signal (refer to the waveform m shown in FIG. 5) supplied to the output terminal 22 results in one in which the incoming time intervals of the portions to be added become ½ and the difference in amplitude therebetween becomes ½, as compared with the processed signal (refer to the waveform h shown in FIG. 5). Respective spectrum components contained in the averaging-processed signal (refer to the waveform m shown in FIG. 5) waveform respectively reach a double frequency as compared with the original processed signal (refer to the waveform h shown in FIG. 5).

Thus, if the averaging-processed signal (refer to the waveform m shown in FIG. 5) is supplied to the following loop filter, then the phase comparison signal processing circuit according to the second embodiment can transition its pass characteristic of the loop filter to a high frequency. It is, therefore, possible to increase the response speed of the loop filter correspondingly.

Incidentally, although not shown in the figure, circuit sections each comprising the drive circuit 23, the gate circuit 24, the voltage hold circuit 25, the averaging circuit 26, the addition circuit 27 and the delay circuit 28 are cascade-connected in the form of two steps between the output end of the addition circuit 14 and the output terminal 22, and such processing operations as described above are carried out at the respective circuit sections. Consequently, the response speed of the loop filter can further be increased if each of the incoming time intervals of portions to be added in the averaging-processed signal obtained at the output terminal 22 is set to ¼ and the difference in amplitude therebetween is set to ¼.

While the preferred forms of the present invention have been described, it is to be understood that modifications will be apparent to those skilled in the art without departing from the spirit of the invention. The scope of the invention is to be determined solely by the following claims.

What is claimed is:

1. A phase comparison signal processing circuit which is connected between a phase comparator and a loop filter in a PLL constituted of a voltage controlled oscillator, the phase comparator, the loop filter and a reference signal generator and processes a rectangular wave signal outputted from the phase comparator, said phase comparison signal processing circuit comprising:
a voltage shifter which converts the rectangular wave signal into a bipolar signal;
first and second signal paths both parallel-connected between the voltage shifter and an output terminal for outputting a processed signal and each comprising a rectifying circuit, an integration holding circuit, a differentiation circuit, a gate circuit, a voltage hold circuit, and an addition circuit common to both signal paths; and
a control signal generator which is driven by the rectangular wave signal and generates control signals for individually controlling the respective integration holding circuits and the respective gate circuits of the first and second signal paths,
wherein in the first signal path, the rectifying circuit extracts a positive portion of the bipolar signal, the integration holding circuit integrates the extracted positive signal and holds an integrated value thereof during a period up to extraction of the positive signal and the following positive signal, the differentiation circuit detects a hold voltage at the time that the hold voltage of the integration holding circuit is changed to a reference voltage, as a differential output, and the gate circuit and the voltage hold circuit output the differential output of the differentiation circuit as a hold voltage corresponding to the interval period, and
wherein in the second signal path, the same processing as that executed in the first signal path is effected on a negative portion of the bipolar signal, whereby a processed signal produced by adding the respective hold voltages obtained in the first and second signal paths is outputted from the output terminal.

2. The phase comparison signal processing circuit according to claim 1, wherein a gate circuit and a voltage hold circuit which form a delay-processed signal obtained by delaying the processed signal outputted from the common addition circuit by a half cycle, using a control signal generated from the control signal generator, and an averaging circuit which is supplied with the processed signal outputted from the common addition circuit and the delay-processed signal and averages signal levels thereof, are cascade-connected between an output end of the addition circuit common to the first and second signal paths and the output terminal, and
wherein an averaging-processed signal in which incoming time intervals of portions to be added become ½ and a difference in amplitude therebetween becomes ½, is outputted from the output terminal connected to the averaging circuit.
